(19) United States
(12) Patent Application Publication
(10) Pub. No.: US 2025/0204004 A1
(43) Pub. Date: Jun. 19, 2025

(54) SEMICONDUCTOR DEVICE

(71) Applicant: SAMSUNG ELECTRONICS CO., LTD., Suwon-si (KR)

(72) Inventors: Jinmyoung LEE, Suwon-si (KR); Kyenhee LEE, Suwon-si (KR)

(21) Appl. No.: 18/761,575

(22) Filed: Jul. 2, 2024

(30) Foreign Application Priority Data
Dec. 19, 2023 (KR) 10-2023-0186071

(51) Int. Cl. H01L 29/417; H01L 23/528; H01L 29/06; H01L 29/161; H01L 29/267; H01L 29/66; H01L 29/775; H01L 29/786

(52) U.S. Cl. CPC H10D 64/254; H01L 23/5286; H10D 62/82; H10D 62/832; H10D 64/258; H10D 30/014; H10D 30/43; H10D 30/6757; H10D 62/121

(57) ABSTRACT

A semiconductor device includes a substrate insulating layer. A gate structure extends in a first direction on the substrate insulating layer. A first source/drain structure and a second source/drain structure are arranged on one side of the gate structure and are spaced apart from each other in the first direction. An etch stop layer is disposed between a second peripheral source/drain region and a second molded layer of the second source/drain structure. The etch stop layer includes a material different from materials of the second peripheral source/drain region and the second molded layer. A first central source/drain region of the first source/drain structure has a first conductivity-type, and a second central source/drain region of the second source/drain structure has a second conductivity-type that is different from the first conductivity-type.

### CROSS-REFERENCE TO RELATED APPLICATION(S)

This application claims priority under 35 U.S.C. § 119 to Korean Patent Application No. 10-2023-0186071, filed on Dec. 19, 2023 in the Korean Intellectual Property Office, the disclosure of which is incorporated by reference in its entirety herein.

### 1. Technical Field

The present inventive concept relates to a semiconductor device.

### 2. Discussion of Related Art

The degree of integration of semiconductor devices has been increasing along with the increased demand for semiconductor devices having high performance, high speed, and/or multifunctionality. A backside power delivery network (BSPDN) structure in which a power rail is disposed on a rear surface of a wafer is being developed to provide semiconductor devices having a high degree of integration. Additionally, to overcome limitations in operating characteristics due to a reduction in size of a planar metal oxide semiconductor FET (MOSFET), research is being conducted to develop semiconductor devices including FinFETs having a three-dimensional channel.

### SUMMARY

An aspect of the present inventive concept may be to provide a semiconductor device having increased reliability.

According to an embodiment of the present disclosure, a semiconductor device includes a substrate insulating layer. A gate structure extends in a first direction on the substrate insulating layer. A first source/drain structure and a second source/drain structure are arranged on one side of the gate structure and are spaced apart from each other in the first direction. The first source/drain structure includes a first central source/drain region, a first peripheral source/drain region surrounding side and lower surfaces of the first central source/drain region, and a first molded layer directly contacting a lower surface of the first peripheral source/drain region. The second source/drain structure includes a second central source/drain region, a second peripheral source/drain region surrounding side and lower surfaces of the second central source/drain region, a second molded layer disposed below the second peripheral source/drain region. An etch stop layer is disposed between the second peripheral source/drain region and the second molded layer. The etch stop layer includes a material that is different from a material of the second peripheral source/drain region and a material of the second molded layer. The first central source/drain region has a first conductivity-type, and the second central source/drain region has a second conductivity-type that is different from the first conductivity-type.

According to an embodiment of the present disclosure, a semiconductor device includes a substrate insulating layer. A gate structure extends in a first direction on the substrate insulating layer. A plurality of source/drain structures is spaced apart from each other in the first direction on one side of the gate structure. The plurality of source/drain structures including a first group of source/drain structures and a second group of source/drain structures. A backside contact plug passes through the substrate insulating layer and is connected to the first group of source/drain structures. Each of the plurality of source/drain structures includes a central source/drain region and a peripheral source/drain region surrounding the central source/drain region. The second group of source/drain structures further include a molded layer directly contacting a lower surface of the peripheral source/drain regions.

According to an embodiment of the present disclosure, a semiconductor device includes a gate structure extending in one direction. A source/drain structure is disposed outside the gate structure. A backside contact plug is electrically connected to the source/drain structure and is disposed below the source/drain structure. The source/drain structure includes a central source/drain region and a peripheral source/drain region surrounding the central source/drain region. The peripheral source/drain region includes a plurality of protrusions protruding towards the gate structure. The peripheral source/drain region includes a non-silicon element in a first concentration. The central source/drain region includes a first epitaxial layer including a non-silicon element in a second concentration that is higher than the first concentration. The first epitaxial layer covers an inner side surface of the peripheral source/drain region. A second epitaxial layer includes a non-silicon element in a third concentration that is higher than the second concentration. The second epitaxial layer is disposed on the first epitaxial layer. The backside contact plug is in direct contact with the peripheral source/drain region.

### BRIEF DESCRIPTION OF DRAWINGS

The above and other aspects, features, and advantages of embodiments of the present inventive concept will be more clearly understood from the following detailed description, taken in conjunction with the accompanying drawings, in which:

FIG. 1 is a schematic plan view illustrating a semiconductor device according to an example embodiment.

FIGS. 2 and 3 are schematic cross-sectional views illustrating a semiconductor device according to example embodiments.

FIG. 4 is a schematic plan view illustrating a semiconductor device according to example embodiments.

FIGS. 5 to 10 are schematic plan views illustrating a semiconductor device according to example embodiments.

FIGS. 11A to 11B are schematic process flow diagrams illustrating a method of manufacturing a semiconductor device according to example embodiments.

FIGS. 12A to 12O are views illustrating a process sequence illustrating a method of manufacturing a semiconductor device according to example embodiments.

### DETAILED DESCRIPTION OF EMBODIMENTS

Hereinafter, embodiments of the present inventive concept will be described with reference to the accompanying drawings. Hereinafter, it can be understood that terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated.

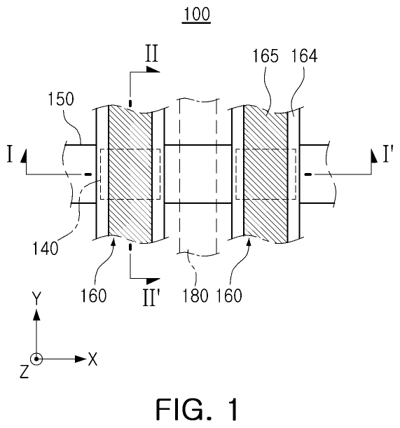

FIG. 1 is a schematic plan view illustrating a semiconductor device according to an example embodiment.

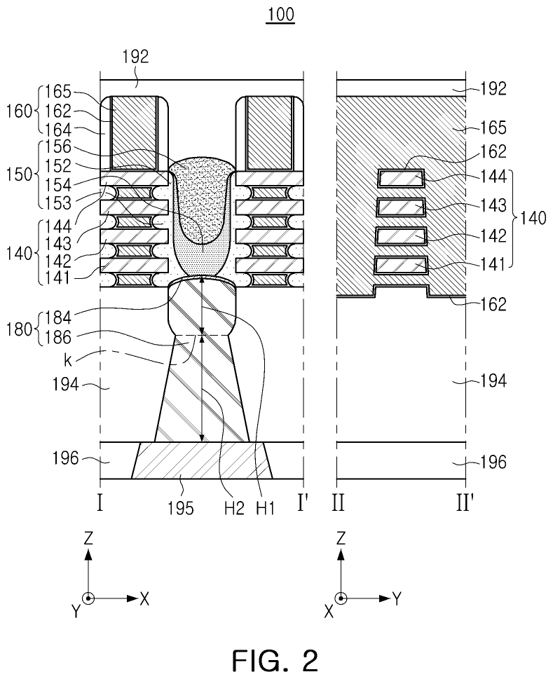

FIG. 2 illustrates schematic cross-sectional views illustrating a semiconductor device according to an example embodiment. FIG. 2 illustrates cross-sections of the semiconductor device of FIG. 1, taken along lines I-I′ and II-II′. For convenience of explanation, only some components of the semiconductor device are illustrated in FIG. 1.

Referring to FIGS. 1 to 2, in an embodiment a semiconductor device 100 may include a substrate insulating layer 194, gate structures 160 extending longitudinally on the substrate insulating layer 194 in one direction (e.g., the Y direction) and respectively including a gate electrode 165, channel structures 140 including first to fourth channel layers 141, 142, 143, and 144 arranged on the substrate insulating layer 194 to be vertically spaced apart from each other (e.g., in the Z direction), source/drain structures 150 contacting the channel structures 140, a backside contact plug 180 passing through the substrate insulating layer 194 (e.g., in the Z direction) and connected to the source/drain structures 150, and a lower interconnection 195 connected to the backside contact plug 180. The semiconductor device 100 may further include first and second interlayer insulating layers 192 and 196.

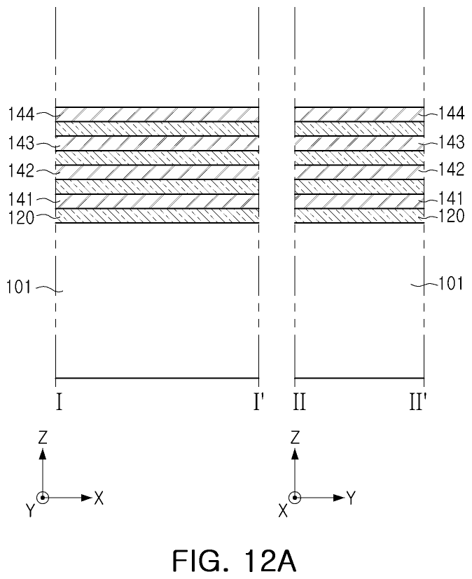

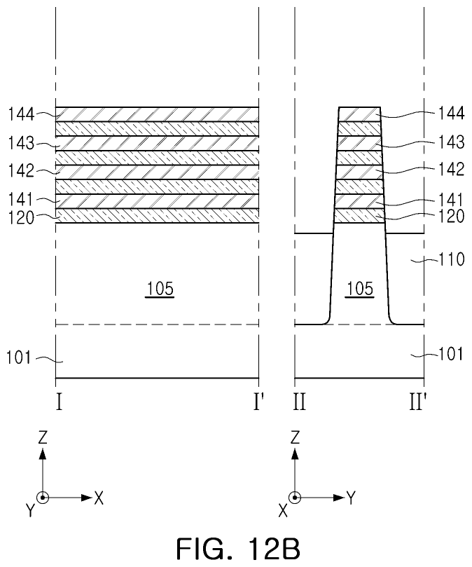

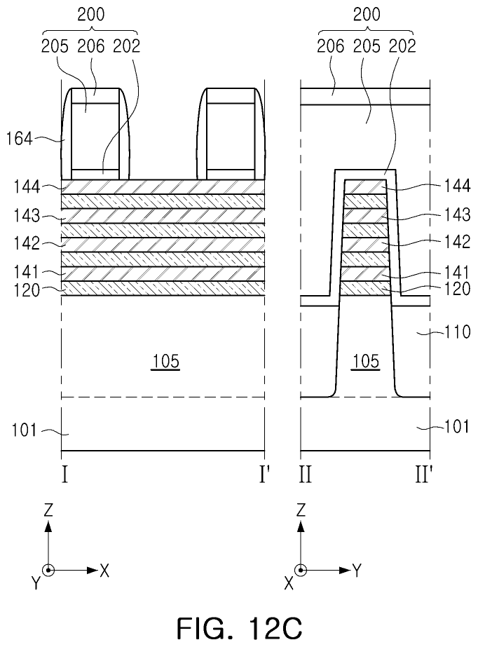

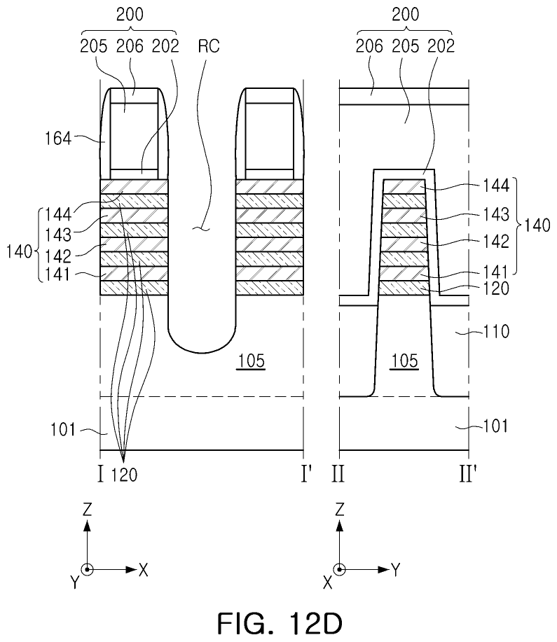

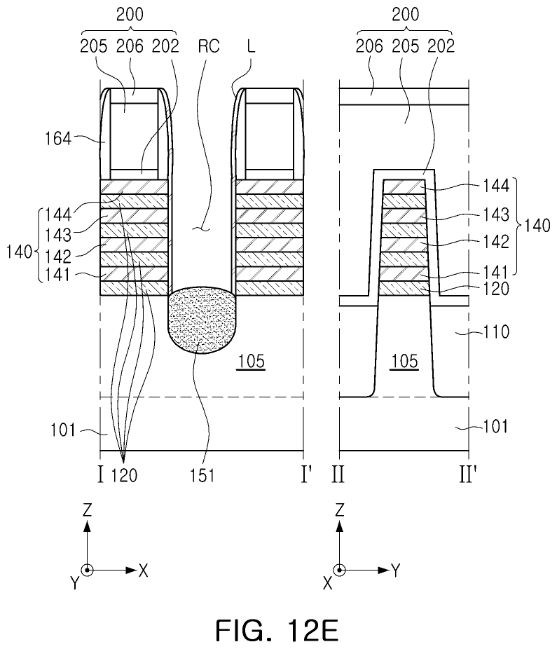

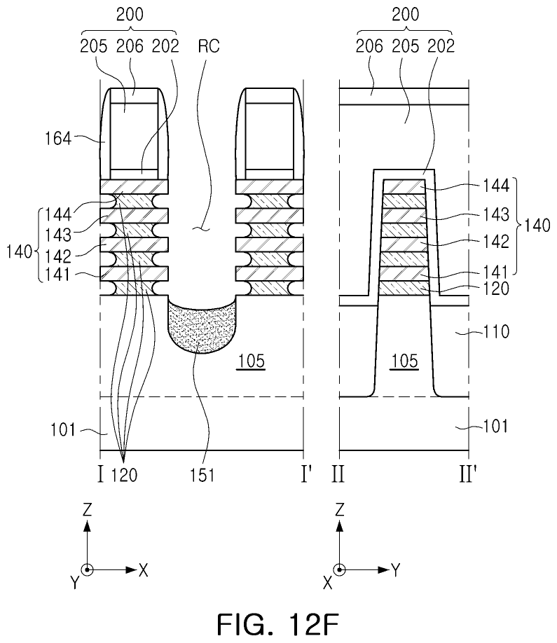

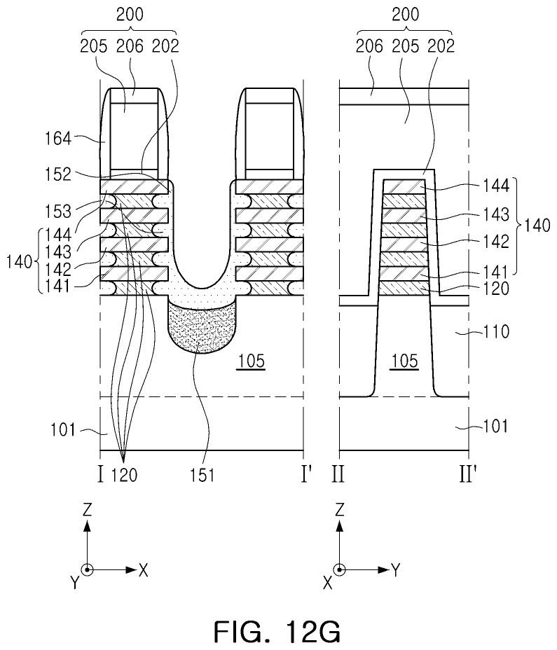

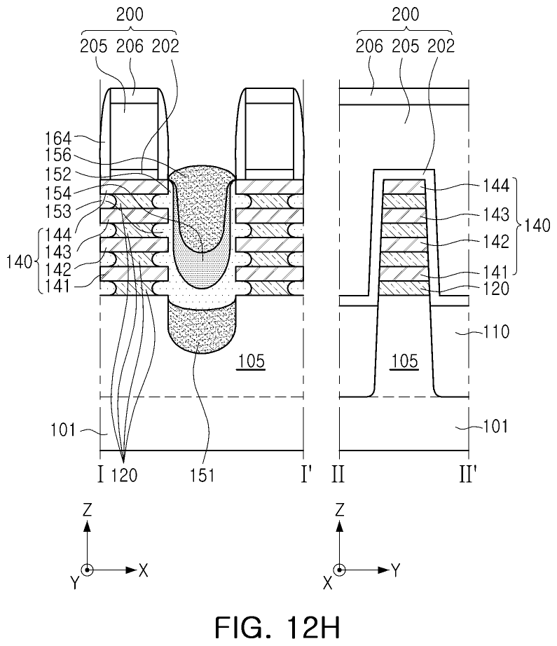

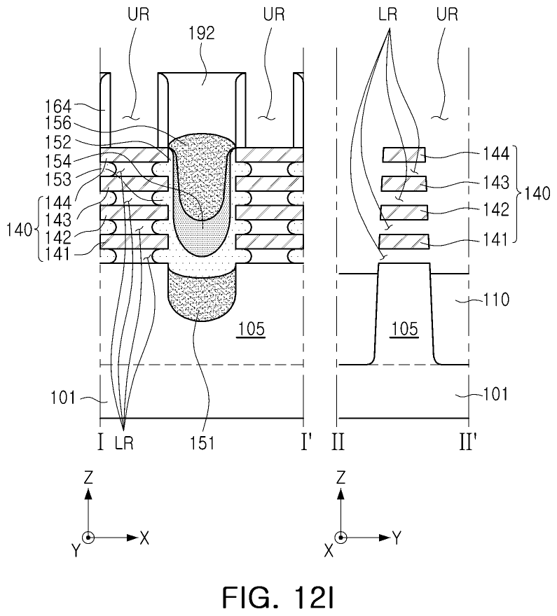

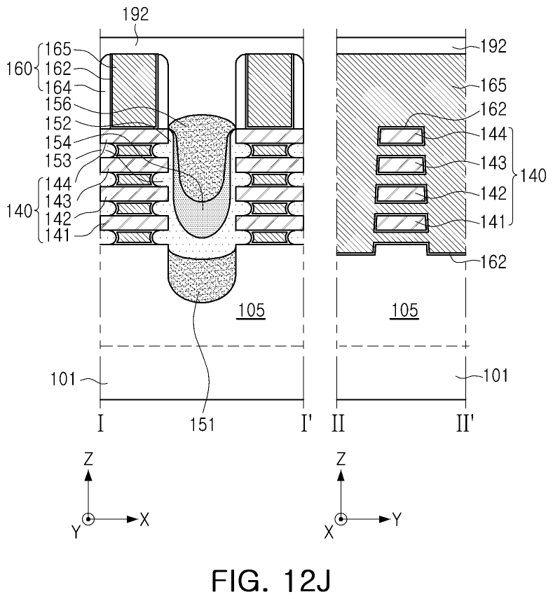

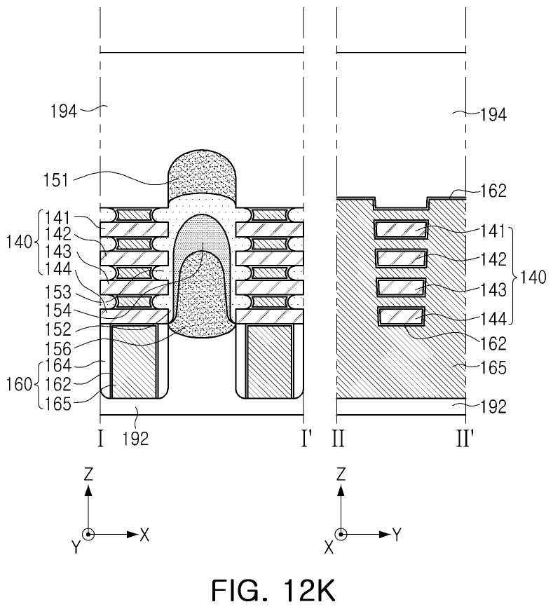

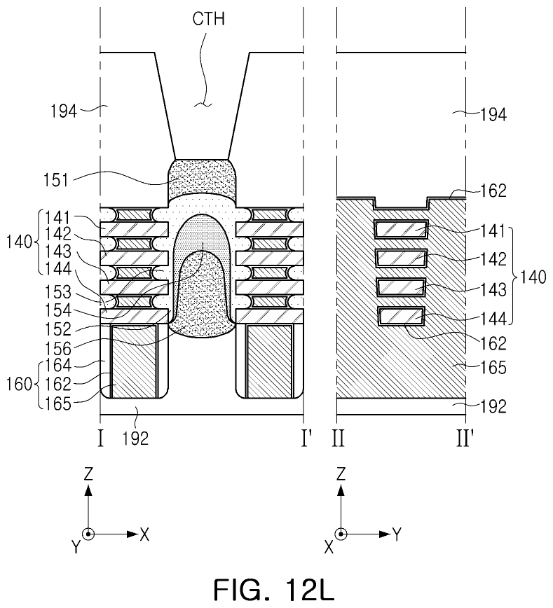

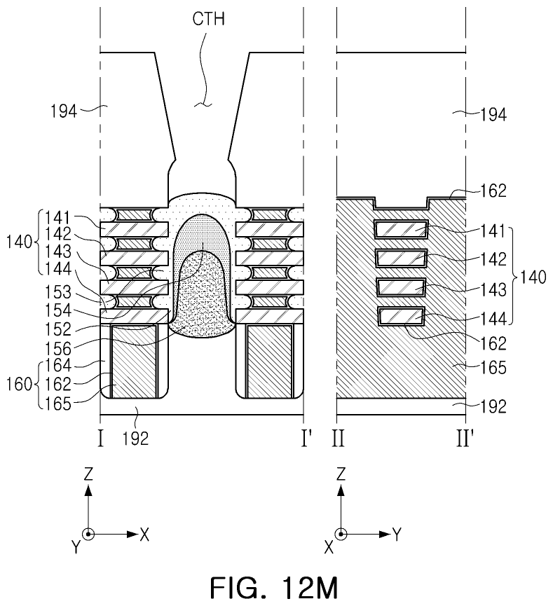

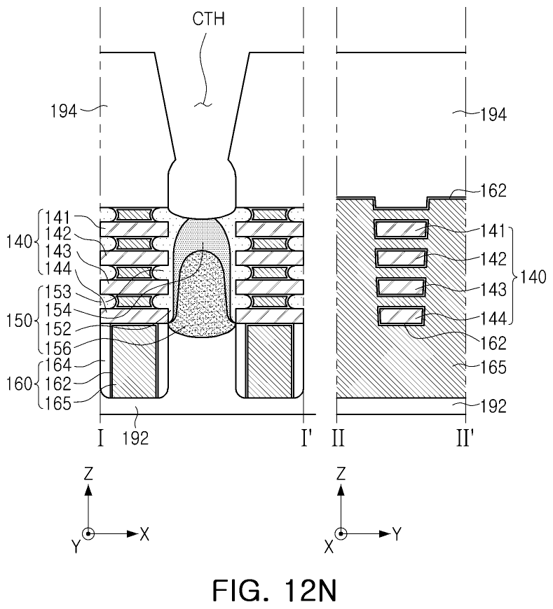

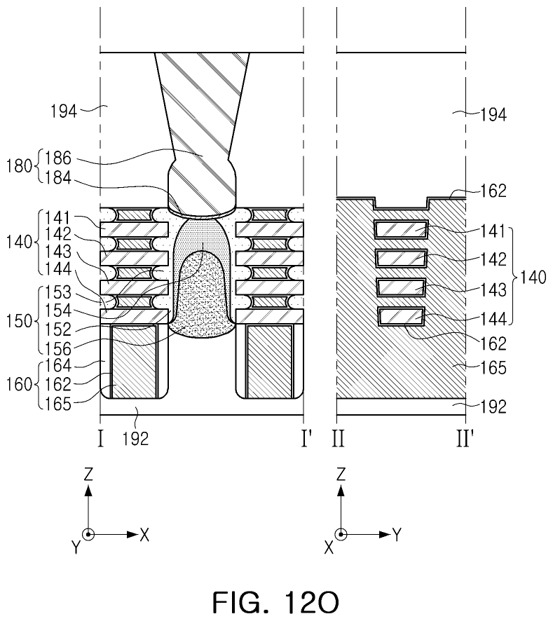

The substrate insulating layer 194 may have an upper surface extending in X and Y directions. In an embodiment, the substrate insulating layer 194 may be a layer formed by removing and/or oxidizing a substrate 101 (see FIG. 12A) formed of a semiconductor material during a manufacturing process. In an embodiment, the substrate insulating layer 194 may be formed of an insulating material, and may include, for example, an oxide, a nitride, or a combination thereof. Depending on embodiments, the substrate insulating layer 194 may include a plurality of insulating layers.

In an embodiment, the gate structures 160 may be arranged to extend longitudinally in one direction, for example, the Y direction, on the substrate insulating layer 194. A channel region of transistors may be formed in the channel structures 140 intersecting the gate electrode 165 of the gate structures 160. The gate structures 160 may be arranged to be spaced apart from each other in the X direction. In an embodiment, each of the gate structures 160 may include gate dielectric layers 162, gate spacer layers 164, and a gate electrode 165. In example embodiments, each of the gate structures 160 may further include a capping layer on an upper surface of the gate electrode 165.

The gate dielectric layers 162 may be disposed between the substrate insulating layer 194 and the gate electrode 165 and between the channel structure 140 and the gate electrode 165, and may be disposed to cover at least a portion of surfaces of the gate electrode 165. For example, in an embodiment the gate dielectric layers 162 may be arranged to surround the surfaces of the gate electrode 165, such as the lateral side surfaces and the bottom surface of the gate electrode 165 and may expose an uppermost surface of the gate electrode 165. The gate dielectric layers 162 may extend between (e.g., directly therebetween) the gate electrode 165 and the gate spacer layers 164. However, embodiments of the present disclosure are not necessarily limited thereto. The gate dielectric layer 162 may include an oxide, a nitride, or a high-k material. The high-K material may refer to a dielectric material having a higher dielectric constant than a silicon oxide film (SiO₂). In an embodiment, the high-K material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHf×O_{y}), hafnium aluminum oxide (HfAlₓO_{y}), or praseodymium oxide (Pr₂O₃). Depending on embodiments, the gate dielectric layer 162 may have a multilayer structure.

In an embodiment, the gate electrode 165 may include a conductive material, and may include, for example, a metal nitride such as titanium nitride (TiN), tantalum nitride (TaN), tungsten nitride (WN), and/or a metal material such as aluminum (Al), tungsten (W), or molybdenum (Mo), or the like, or a semiconductor material such as doped polysilicon. Depending on embodiments, the gate electrode 165 may have a multilayer structure. In an embodiment, the gate electrodes 165 may be connected in a region to upper contact plugs disposed thereon.

The channel structures 140 may be disposed on the substrate insulating layer 194 to intersect the gate structures 160. In an embodiment, each of the channel structures 140 may include the first to fourth channel layers 141, 142, 143, and 144, which may be two or more channel layers arranged to be spaced apart from each other in a Z direction. The channel structures 140 may be connected to the source/drain structures 150. In an embodiment, the channel structures 140 may have a width that is equal to or similar to a width of the gate structures 160 in the X direction. In a cross-section in the Y direction, among the first to fourth channel layers 141, 142, 143, and 144, a channel layer disposed in a lower portion may have a width (e.g., length in the Y direction) that is equal to or larger than a width of a channel layer disposed in an upper portion. In some embodiments, the channel structures 140 may have a reduced width, as compared to the gate structures 160, such that side surfaces thereof are located below the gate structures 160 in the X direction.

In an embodiment, the channel structures 140 may be formed of a semiconductor material, and may include, for example, at least one of silicon (Si), silicon germanium (SiGe), and germanium (Ge). However, embodiments of the present disclosure are not necessarily limited thereto and the number and shapes of channel layers forming one channel structure 140 may be changed in various embodiments.

In the semiconductor device 100 according to an embodiment, the gate electrode 165 may be disposed between the first to fourth channel layers 141, 142, 143, and 144 of the channel structures 140 (e.g., in the Z direction) and on the channel structures 140 (e.g., directly above the channel structures 140). Therefore, the semiconductor device 100 may include a transistor with a MBCFET™ (a multi bridge channel FET) structure, which may be a gate-all-around type field effect transistor.

The source/drain structures 150 may be disposed on both sides of the gate structures 160 to directly contact the channel structures 140. For example, in an embodiment the source/drain structures 150 may be arranged to cover side surfaces of each of the first to fourth channel layers 141, 142, 143, and 144 of the channel structure 140 in the X direction. The source/drain structures 150 may be connected to the backside contact plug 180 through a lower surface or a lower end thereof. A lower region of the source/drain structure 150 may have a recessed shape by the backside contact plug 180. The source/drain structure 150 may be electrically connected to the lower interconnection 195 through the backside contact plug 180, and may receive power. In an embodiment, an upper surface of the source/drain structure 150 may be positioned at a higher level than a lower surface of the gate electrode 165 on the channel structure 140. However, embodiments of the present disclosure are not necessarily limited thereto, and the upper surface of the source/drain structure 150 may be positioned at a level, equal or similar to the lower surface of the gate electrode 165 on the channel structure 140, and the height may be changed in various embodiments.

The source/drain structure 150 may include a peripheral source/drain region 152 and a central source/drain region 154 and 156, arranged sequentially from the bottom. In an embodiment, the central source/drain region may include a first epitaxial layer 154 and a second epitaxial layer 156. The peripheral source/drain region 152 covers side surfaces of each of the first to fourth channel layers 141, 142, 143, and 144 in the X direction, and may cover side surfaces of the gate structures 160 below the channel structure 140 in the X direction. The peripheral source/drain region 152 may cover an inner side surface of a recess region RC (see FIG. 12F) in which the source/drain structure 150 is disposed, and may be arranged to be spaced apart from an adjacent peripheral source/drain region 152 by the backside contact plug 180. In an embodiment, the peripheral source/drain region 152 may include a plurality of protrusions 153 extending from a side surface of the first peripheral source/drain region facing the gate structure 160 and protruding towards the gate structure 160. Therefore, the peripheral source/drain region 152 may have outer side surfaces protruding convexly towards the gate structures 160, and bending may occur in the outer side surfaces. The plurality of protrusions 153 may be arranged to protrude towards the gate structure 160 (e.g., in the X direction) from below each of the first to fourth channel layers 141, 142, 143, and 144 stacked vertically. In an embodiment, a portion of surfaces in the lower region of the peripheral source/drain region 152 may be in direct contact with the backside contact plug 180, and may have a curved shape following a shape of the backside contact plug 180.

The central source/drain region (154 and 156) may cover the peripheral source/drain regions 152, and may fill the recess region RC (see FIG. 12F). In an embodiment, a lower surface of the central source/drain region (154 and 156) may be in contact with the backside contact plug 180, and may have a curved surface following the shape of the backside contact plug 180. The central source/drain region (154 and 156) may include the first epitaxial layer 154 covering an inner side surface of the peripheral source/drain regions 152 and a portion of an upper surface of the backside contact plug 180, and the second epitaxial layer 156 disposed on the first epitaxial layer 154 and covering inner side surfaces of the first epitaxial layer 154 and upper surfaces of the peripheral source/drain regions 152 and the first epitaxial layer.

In an embodiment, the source/drain structures 150 may include a semiconductor material, for example, at least one of silicon (Si) or germanium (Ge), and may further include impurities. The peripheral source/drain region 152, the first epitaxial layer 154, and the second epitaxial layer 156 may be epitaxially grown epitaxial layers, and may have different compositions from each other. In an embodiment, the peripheral source/drain region 152, the first epitaxial layer 154, and the second epitaxial layer 156 may include non-silicon elements, identical to each other, but concentrations of the non-silicon elements in each configuration may be different from each other. For example, the peripheral source/drain region 152 may have a concentration of the non-silicon element, which may be a first concentration, the first epitaxial layer 154 may have a concentration of the non-silicon element, which may be a second concentration, the second epitaxial layer 156 may have a concentration of the non-silicon element, which may be a third concentration. In an embodiment, the third concentration may be greater than the second concentration, and the second concentration may be greater than the first concentration. The non-silicon element may be, for example, germanium (Ge) and/or a doping element.

In an embodiment, the semiconductor device 100 may be, for example, a pFET. In this embodiment, the source/drain structure 150 may include silicon germanium (SiGe), and the non-silicon element may be germanium (Ge). The source/drain structure 150 may include a doping element, such as impurities. In an embodiment, the impurities in the source/drain structure 150 of the semiconductor device 100, which may be a pFET, may be at least one of boron (B), gallium (Ga), or indium (In).

The backside contact plug 180 may be disposed below the source/drain structure 150. The backside contact plug 180 may pass through the substrate insulating layer 194 (e.g., in the Z direction), and may be connected to the source/drain structure 150. The backside contact plug 180 may be disposed to partially recess the lower region of the source/drain structure 150, and be in direct contact with a recessed lower surface of the source/drain structure 150. The backside contact plug 180 may have an upper surface that may be convex in an upward direction, e.g., an upper surface that may be convex in a direction towards the source/drain structure 150. In an embodiment, an upper end of the backside contact plug 180 may be positioned at a higher level than a lower end of the gate structure 160. In an embodiment, the upper surface of the backside contact plug 180 may be in direct contact with the peripheral source/drain region 152 and the central source/drain region of the source/drain structure 150, such as a lower surface of the first epitaxial layer 154. A level of the upper end of the backside contact plug 180 may be higher than a level of a lower end of the source/drain structure 150. The backside contact plug 180 may have a kink portion k having a minimum width between the upper and lower ends of the backside contact plug 180. In an embodiment, a distance H1 (e.g., length in the Z direction) between the kink portion k and the upper end of the backside contact plug 180 may be less than a distance H2 (e.g., length in the Z direction) between the kink portion k and the lower end of the backside contact plug 180. For example, the kink portion may be located closer to the upper end of the backside contact plug 180 than to the lower end of the backside contact plug 180. A lower surface of the backside contact plug 180 may be coplanar (e.g., in the Z direction) with a lower surface of the substrate insulating layer 194.

In an embodiment, the backside contact plug 180 may include a metal-semiconductor compound layer 184 and a conductive layer 186. The metal-semiconductor compound layer 184 may be located on the upper end of the backside contact plug 180, and may form at least a portion of the upper surface of the backside contact plug 180. The metal-semiconductor compound layer 184 may define the upper surface of the backside contact plug 180. In an embodiment, the metal-semiconductor compound layer 184 may be disposed at least in a region in which the backside contact plug 180 is in direct contact with the source/drain structure 150. However, in embodiments, the scope of the metal-semiconductor compound layer 184 is not necessarily limited to that illustrated. The metal-semiconductor compound layer 184 may be, for example, a metal silicide layer. In an embodiment, the conductive layer 186 may form the backside contact plug 180, together with the metal-semiconductor compound layer 184, and may be arranged to fill a contact hole CTH (see FIG. 12N). The conductive layer 186 may include a metal material such as aluminum (Al), tungsten (W), molybdenum (Mo), or the like. In example embodiments, the number and arrangement of conductive layers constituting the backside contact plug 180 may be changed. In some embodiments, the metal-semiconductor compound layer 184 may be omitted.

In this embodiment, since the peripheral source/drain region 152 may include the plurality of protrusions 153, the backside contact plug 180 and the gate electrode 165 may be arranged to be stably spaced apart from each other. In an embodiment, the peripheral source/drain region 152 may be used as an etch stop element when forming the backside contact plug 180 (see FIG. 12M), a process may be simplified and a semiconductor device having increased reliability may be provided.

The lower interconnection 195 may be connected to (e.g., directly connected thereto) the lower end or the lower surface of the backside contact plug 180. The lower interconnection 195, together with the backside contact plug 180, may form a backside power delivery network (BSPDN) that applies power or ground voltage, and may also be referred to as a rear power rail or an embedded power rail. For example, in an embodiment the lower interconnection 195 may be a buried interconnection line extending longitudinally in one direction, for example, the Y direction, below the backside contact plug 180. However, embodiments of the present disclosure are not necessarily limited thereto and a shape of the lower interconnection 195 may vary. For example, in some embodiments, the lower interconnection 195 may include a via region and/or a line region. An upper surface of the lower interconnection 195 may be coplanar with an upper surface of the second interlayer insulating layer 196. In an embodiment, a width (e.g., length in the X direction) of the upper surface of the lower interconnection 195 may be greater than a width (e.g., length in the X direction) of the lower surface of the backside contact plug 180. In an embodiment, a width of the lower interconnection 195 may continuously increase from an upper portion of the lower interconnection 195 to a lower portion thereof. However, embodiments of the present disclosure are not necessarily limited thereto. In an embodiment, the lower interconnection 195 may include a conductive material, for example, at least one of tungsten (W), copper (Cu), aluminum (Al), cobalt (Co), ruthenium (Ru), titanium (Ti), or molybdenum (Mo).

The first interlayer insulating layer 192 may be disposed to cover upper surfaces of the source/drain structures 150 and the gate structures 160. The second interlayer insulating layer 196 may be disposed to cover the lower surface of the substrate insulating layer 194 and surround the lower interconnection 195.

In an embodiment, the first and second interlayer insulating layers 192 and 196 may include at least one of an oxide, a nitride, or an oxynitride, and may include, for example, a low-K material. Depending on embodiments, each of the first and second interlayer insulating layers 192 and 196 may include a plurality of insulating layers.

The semiconductor device 100 may be flipped upside down and packaged with the structure of FIG. 2 such that the lower interconnection 195 is located in an upper portion. However, embodiments of the present disclosure are not necessarily limited thereto and a packaging form of the semiconductor device 100 may vary. Since the source/drain structures 150 may be connected to (e.g., electrically connected thereto) the lower interconnection 195, disposed in a lower portion, through the backside contact plug 180, integration may be increased.

In the description of the following embodiments, descriptions overlapping the above description with reference to FIGS. 1 and 2 may be omitted for economy of description.

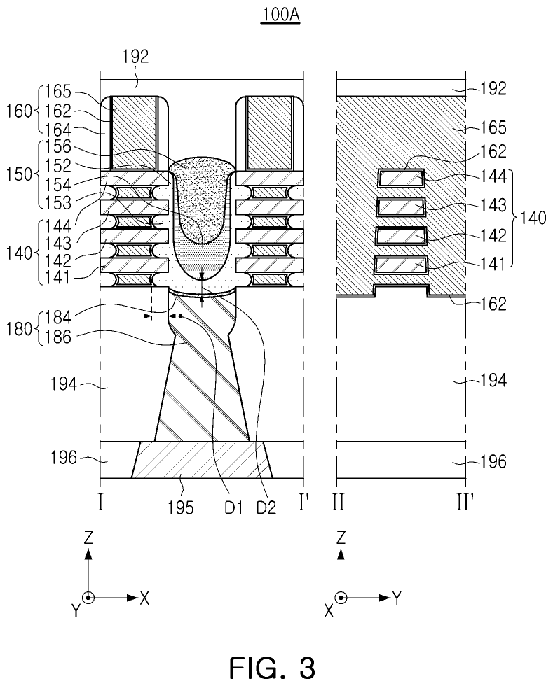

FIG. 3 is a schematic cross-sectional view illustrating a semiconductor device according to an example embodiment.

Referring to FIG. 3, a peripheral source/drain region 152 of a semiconductor device 100A may cover a lower surface of a central source/drain region (154 and 156), and a backside contact plug 180 and the central source/drain region (154 and 156) may be spaced apart from each other (e.g., in the Z direction). An upper surface of the backside contact plug 180 may be formed along a lower surface of a source/drain structure 150, and may have a shape convex in a downward direction towards the lower interconnection 195. A protrusion length D1 of a protrusion 153 between an end of the protrusion 153 and the peripheral source/drain region 152 in the X direction, and a distance D2 (e.g., length in the Z direction) between a lower end of the central source/drain region (154 and 156) and a lower end of the peripheral source/drain region 152 may be changed depending on an embodiment. In an embodiment, the protrusion length D1 may be greater than the distance D2 between the lower end of the central source/drain region (154 and 156) and the lower end of the peripheral source/drain regions 152. In an embodiment, the protrusion length D1 may be less than or substantially equal to the distance D2 between the lower end of the central source/drain region (154 and 156) and the lower end of the peripheral source/drain regions 152.

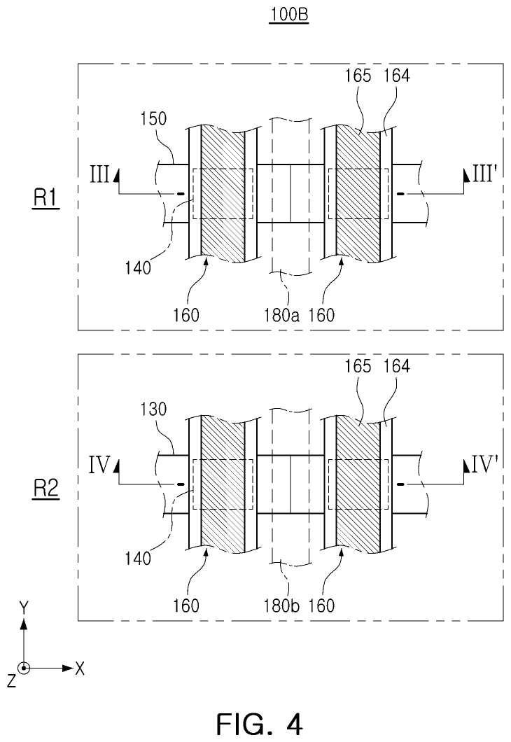

FIG. 4 is a schematic plan view illustrating a semiconductor device according to an example embodiment.

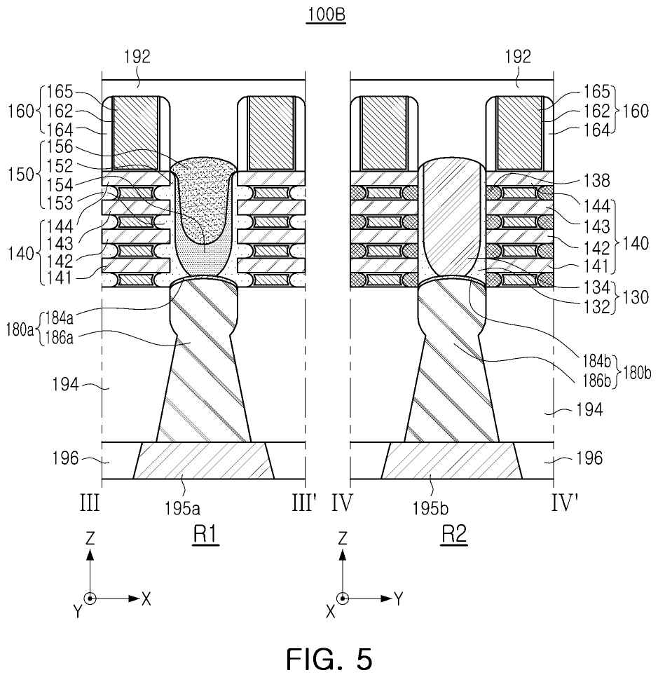

FIG. 5 illustrates schematic cross-sectional views illustrating a semiconductor device according to an example embodiment. FIG. 5 illustrates cross-sections of the semiconductor device of FIG. 4, taken along lines III-III′ and lines IV-IV′. For convenience of explanation, only some components of the semiconductor device are illustrated in FIG. 4.

Referring to FIGS. 4 and 5, a semiconductor device 100B may include a first region R1 and a second region R2. Depending on an embodiment, the first region R1 and the second region R2 may be adjacent regions or may be arbitrary regions spaced apart from each other. In an embodiment shown in FIG. 4, the first and second regions R1, R2 may be spaced apart from each other in the Y direction. However, embodiments of the present disclosure are not necessarily limited thereto. In the first region R1, the semiconductor devices 100 and 100A described above with reference to FIGS. 1 to 3 may be disposed. Among configurations described with reference to FIGS. 1 to 3, the source/drain structure 150, the backside contact plug 180, and the lower interconnection 195 may be respectively referred to as a first source/drain structure 150a, a first backside contact plug 180a, and a first lower interconnection 195a. The first source/drain structure 150 may have a first conductivity-type, and a second source/drain structure 130 may have a second conductivity-type, different from the first conductivity-type. For example, in an embodiment in which the first conductivity-type of the first source/drain structure 150 in the first region R1 is a P-type, the second conductivity-type of the second source/drain structure 130 in the second region R2 may be an N-type.

The second region R2 may include substantially the same configuration as the first region R1, except that second source/drain structures 130, a plurality of inner spacers 138, a second backside contact plug 180b, and a second lower interconnection 195b are included and the second region R2 does not include the first source/drain structure 150, the first backside contact plug 180a and the first lower interconnection 195a.

In an embodiment, the first and second source/drain structures 150 and 130 having different conductivity-types have different structures depending on each conductivity-type, such that reliability of the semiconductor device may be increased.

The second source/drain structure 130 may include a second peripheral source/drain region 132 and a second central source/drain region 134. The second peripheral source/drain region 132 may cover side surfaces of first to fourth channel layers 141, 142, 143, and 144 in the X-direction. Second peripheral source/drain regions 132 may be arranged to be spaced apart in the X direction in one second source/drain structure 130 by the second backside contact plug 180b. A portion of surfaces in a lower region of the second peripheral source/drain region 132 may be in direct contact with the second backside contact plug 180b, and may have a curved shape following a shape of the second backside contact plug 180b. In an embodiment, the second peripheral source/drain region 132 may include a material that is identical to a material of the first peripheral source/drain region 152, and may have a concentration of the non-silicon element, which may be a first concentration, that is the same as the first peripheral source/drain region 152.

The second central source/drain region 134 may be disposed on (e.g., disposed directly thereon) the second peripheral source/drain region 132. The second central source/drain region 134 may include a doping element, such as impurities. In an embodiment, the second central source/drain region 134 may have an N-type conductivity-type, and the impurities may be at least one of phosphorus (P), arsenic (As), or antimony (Sb).

A plurality of inner spacers 138 may be disposed on a side surface of the second source/drain structure 130. The plurality of inner spacers 138 may extend into (e.g., protrude towards) the gate structure 160 below the plurality of channel layers 141, 142, 143, and 144 stacked in a vertical direction, and may cover side surfaces of gate structures 160 in the X direction below the channel structure 140. In an embodiment, the plurality of inner spacers 138 may include a material that is different from a material of the second source/drain structure 130. In an embodiment, the plurality of inner spacers 138 may be formed of an insulating material, and may include, for example, silicon oxide, silicon nitride, or a combination thereof.

The second backside contact plug 180b and the second lower interconnection 195b may have substantially the same characteristics as the first backside contact plug 180a and the first lower interconnection 195a, respectively, except for connection with the second source/drain structure 130.

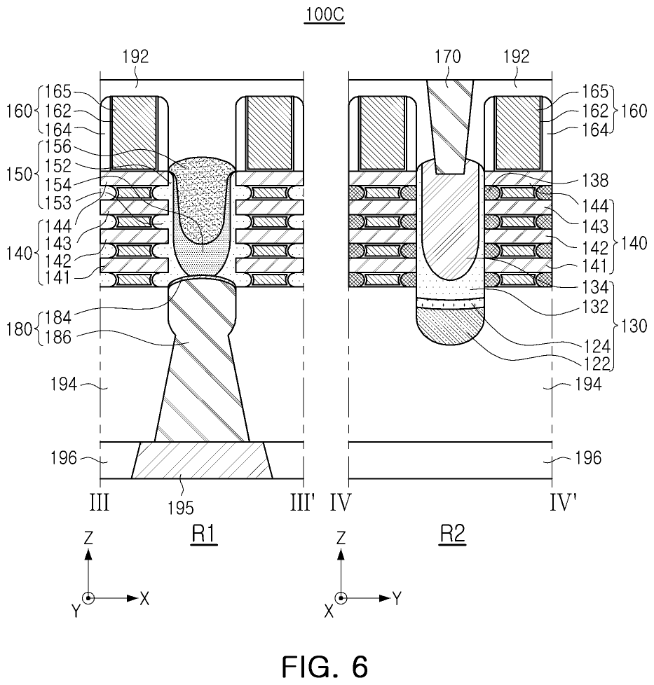

In the following description of FIGS. 6 to 10, contents that overlap with the above description may be omitted for economy of explanation. Unless otherwise explained, it can be understood that the first source/drain structure 150 has a first conductivity-type, and the second source/drain structure 130 has a second conductivity-type, different from the first conductivity-type. In an embodiment, the first conductivity-type may be a P-type, and the second conductivity-type may be an N-type.

FIG. 6 illustrates schematic cross-sectional views illustrating a semiconductor device according to an example embodiment.

Referring to FIG. 6, in a semiconductor device 100C, a first source/drain structure 150 having a first conductivity-type in a first region R1 may be connected to a backside contact plug 180, and a second source/drain structure 130 having a second conductivity-type in a second region R2 may be connected to a frontside contact plug 170. In an embodiment, the frontside contact plug 170 may extend into the second source/drain structure 130 (e.g., in the Z direction) through a first interlayer insulating layer 192. The frontside contact plug 170 may be disposed to partially recess an upper portion of a second central source/drain region 134. The frontside contact plug 170 may have the same or similar characteristics as the back side contact plug 180, except for a position or a shape to be disposed. In an embodiment, the frontside contact plug 170 may include a metal material such as aluminum (Al), tungsten (W), molybdenum (Mo), or the like, and depending on an embodiment, a semiconductor compound layer contacting the second source/drain structure 130 may be included.

The second source/drain structure 130 may further include an etch stop layer 124 and a second molded layer 122, arranged on a lower surface of a second peripheral source/drain region 132. In an embodiment, the etch stop layer 124 may include a material that is different from a material of the second peripheral source/drain region 132 and a material of the second molded layer 122. In an embodiment, the etch stop layer 124 may include an oxide, a nitride, or the like.

The second molded layer 122 may be disposed to directly contact a lower surface of the etch stop layer 124. In an embodiment, the second molded layer 122 may include a semiconductor material, for example, at least one of silicon (Si) or germanium (Ge), and may further include impurities. In an embodiment, the second molded layer 122 may include germanium (Ge) and/or a non-silicon element, which may be a doping element, and may have a non-silicon element concentration that is substantially identical to a non-silicon element concentration of a first molded layer 151.

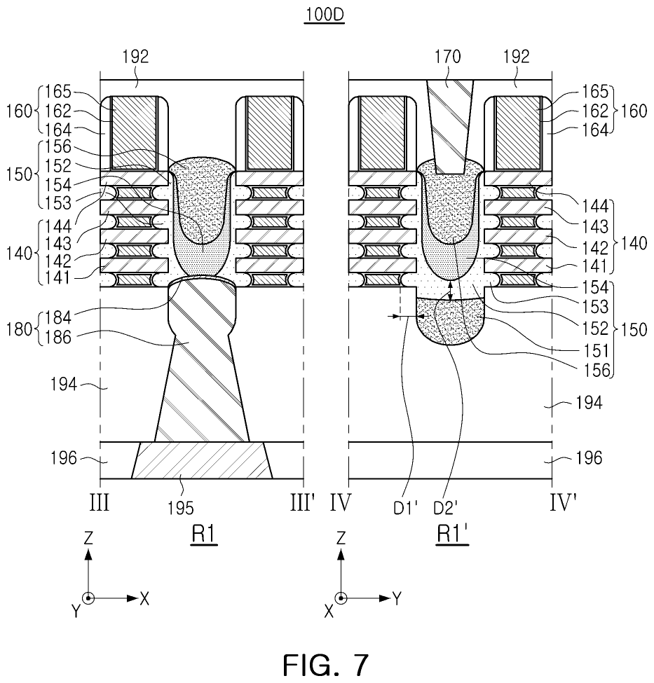

FIG. 7 illustrates schematic cross-sectional views illustrating a semiconductor device according to an example embodiment.

Referring to FIG. 7, a semiconductor device 100D may include 1-1 and 1-2 regions R1 and R1′ in which source/drain structures 150 having a first conductivity-type are disposed. The first regions R1 and R1′ may be adjacent to each other or may be spaced apart from each other. In an embodiment, a first group of source/drain structures 150 disposed in a 1-1 region R1 may be connected to a backside contact plug 180, and a second group of source/drain structures disposed in a 1-2 region R1′ may be connected to a frontside contact plug 170.

The second group of source/drain structures 150 connected to the frontside contact plug 170 may further include a molded layer 151. The molded layer 151 may be in direct contact with a lower surface of a peripheral source/drain region 152. In an embodiment, the molded layer 151 may include a semiconductor material, for example, at least one of silicon (Si) or germanium (Ge), and may further include impurities. In an embodiment, the molded layer 151 may include germanium (Ge) and/or a non-silicon element, which may be a doping element, and a concentration of the non-silicon element in the molded layer 151 may be greater than a first concentration, which may be a concentration of a non-silicon element in the peripheral source/drain region 152, and a second concentration, which may be a concentration of a non-silicon element in a first epitaxial layer 154. The concentration of the non-silicon element in the molded layer 151 may be substantially identical to a third concentration, which may be a concentration of a non-silicon element in a second epitaxial layer 156.

In the second group of source/drain structures 150 disposed in the 1-2 region R1′, a distance D1′ (e.g., length in the X direction) at which a protrusion 153 protrudes from a side surface of the peripheral source/drain region 152 may be less than a distance D2′ (e.g., length in the Z direction) between a lower end of a central source/drain region (154 and 156), such as a lower end of the first epitaxial layer 154, and a lower end of the peripheral source/drain region 152. However, embodiments of the present disclosure are not necessarily limited thereto and depending on an embodiment, a size relationship thereof may be changed in various manners.

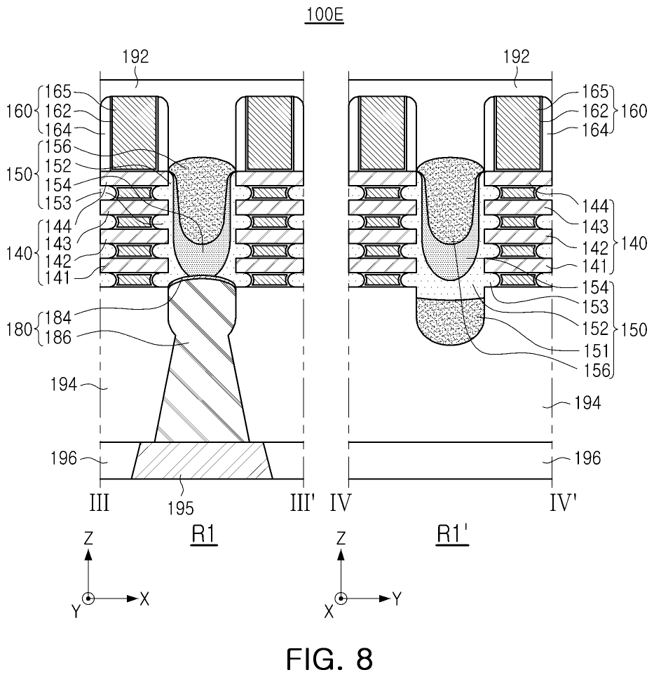

Referring to FIG. 8, in a semiconductor device 100E, unlike the semiconductor device 100D of FIG. 7, a second group of source/drain structures 150 in a 1-2 region R1′ may be a dummy configuration that is not electrically connected to a different component. Unlike a first group of source/drain structures 150 connected to a backside contact plug 180, the second group of source/drain structures 150, which is a dummy configuration, may include a molded layer 151 in a lower portion, such as directly contacting a lower surface of the first peripheral source/drain region 152.

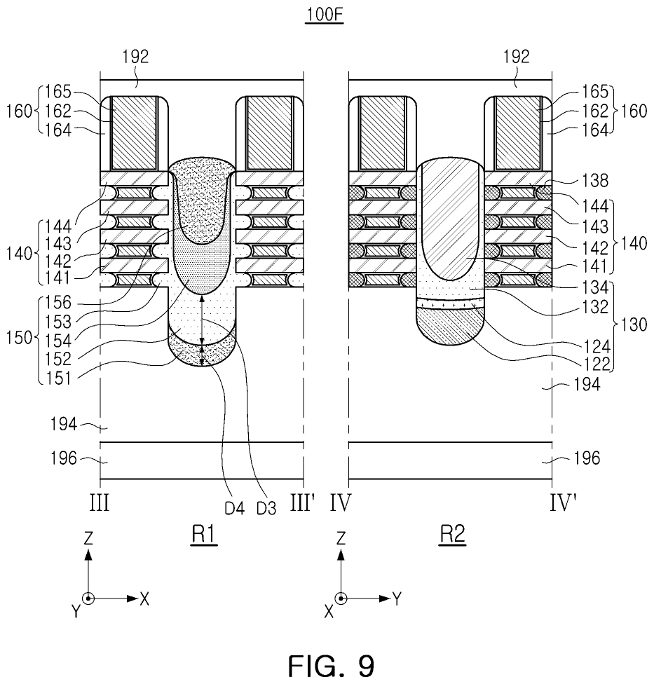

Referring to FIG. 9, a semiconductor device 100F having a first source/drain structure 150 may be disposed in a first region R1, and a second source/drain structure 130 may be disposed in a second region R2. In an embodiment, the first and second source/drain structures 150 and 130 may both be a dummy configuration not electrically connected to a different component. The first source/drain structure 150 may include a first molded layer 151 below (e.g., directly below) a first peripheral source/drain region 152, and the second source/drain structure 130 may include an etch stop layer 124 and a second molded layer 122 below a second peripheral source/drain region 132. In an embodiment, a distance D3 (e.g., length in the Z direction) between a lower end of a central source/drain region (154 and 156) of the first source/drain structure 150, such as a lower end of the first epitaxial layer 154, and a lower end of the peripheral source/drain region 152 may be greater than a distance D4 (e.g., length in the Z direction) between a lower end of the peripheral source/drain region 152 and a lower end of a first molded layer 151.

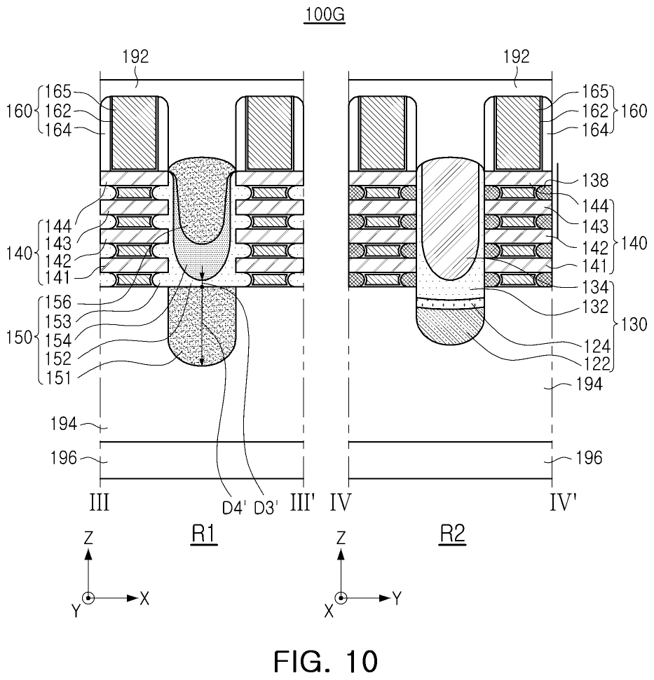

Referring to FIG. 10, in a semiconductor device 100G according to an embodiment, unlike the semiconductor device 100F of an embodiment in FIG. 9, a lower surface of a first source/drain structure 150 in a first region R1 may be located on a level that is substantially equal to a level of a lower surface of a gate structure 160. A distance D3′ (e.g., length in the Z direction) between a lower end of the first central source/drain region (154 and 156), such as a lower end of the first epitaxial layer 154, and a central portion of a lower surface of the first peripheral source/drain region 152 may be less than a height D4′ (e.g., length in the Z direction) of a first molded layer 151 disposed directly on a lower surface of the peripheral source/drain region 152. For example, the height D4′ of the first molded layer 151 may be a distance (e.g., length in the Z direction) between the lower end of the first peripheral source/drain region 152 and the lower end of the first molded layer 151.

Embodiments of regions described with reference to FIGS. 5 to 10 may be combined in various manners in a compatible range. For example, a first source/drain structures 150 in each region may be connected to a first backside contact plug 180a, or a second source/drain structures 130 in each region may be connected to a second backside contact plug 180b.

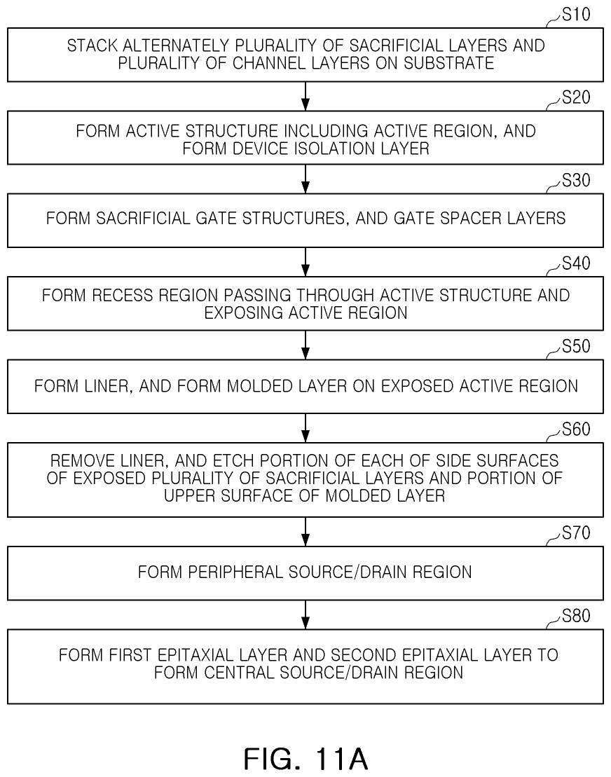

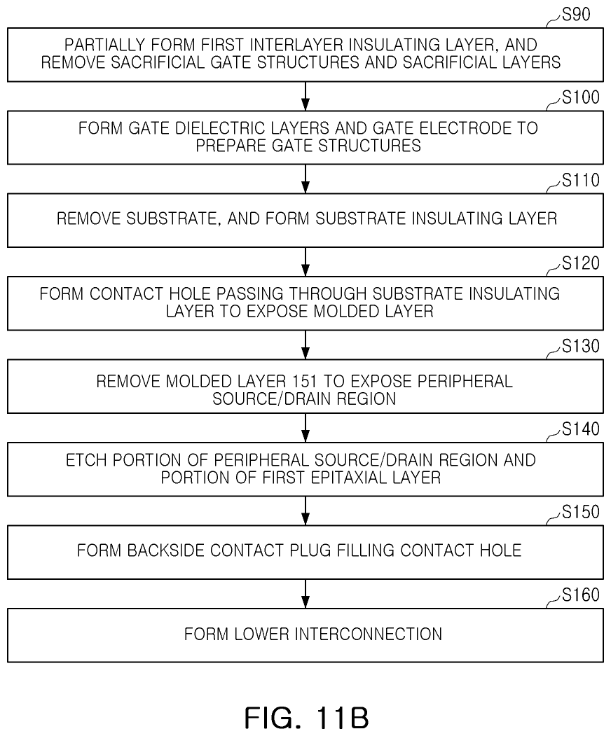

FIGS. 11A to 11B are schematic process flow diagrams illustrating a method of manufacturing a semiconductor device according to example embodiments. FIGS. 12A to 12O are views illustrating a process sequence illustrating a method of manufacturing a semiconductor device according to example embodiments.

Referring to FIGS. 11A and 12A, a plurality of sacrificial layers 120 and a plurality of channel layers 141, 142, 143, and 144 may be alternately stacked on a substrate 101 (e.g., in the Z direction) in block S10.

In an embodiment, the substrate 101 may include silicon (Si), germanium (Ge), or silicon germanium (SiGe). The substrate 101 may include a bulk wafer, an epitaxial layer, a silicon-on-insulator (SOI) layer, or a semiconductor-on-insulator (SeOI) layer.

In an embodiment, the plurality of channel layers 141, 142, 143, and 144 may include first to fourth channel layers 141, 142, 143, and 144. The sacrificial layers 120 may be layers that may be replaced with gate dielectric layers 162 and gate electrodes 165 below the fourth channel layer 144 by a subsequent process, as illustrated in FIG. 2. In an embodiment, the sacrificial layers 120 may be formed of a material having etch selectivity with respect to the first to fourth channel layers 141, 142, 143, and 144, respectively. The first to fourth channel layers 141, 142, 143, and 144 may include a material that is different from materials of the sacrificial layers 120. In an embodiment, the sacrificial layers 120 and the first to fourth channel layers 141, 142, 143, and 144 may include, for example, a semiconductor material including at least one of silicon (Si), silicon germanium (SiGe), or germanium (Ge), but may include different materials, and may or may not include impurities. For example, the sacrificial layers 120 may include silicon germanium (SiGe), and the first to fourth channel layers 141, 142, 143, and 144 may include silicon (Si).

In an embodiment, the sacrificial layers 120 and the first to fourth channel layers 141, 142, 143, and 144 may be formed by performing an epitaxial growth process from the stacked structure. The number of sacrificial layers 120 and the number of channel layers, alternately stacked, may be changed in various embodiments.

Referring to FIGS. 11A and 12B, the sacrificial layers 120, the first to fourth channel layers 141, 142, 143, and 144, and the substrate 101 may be partially removed to form an active structure including an active region 105, and form a device isolation layer 110 in block S20.

The active structure may include the active region 105, the sacrificial layers 120, and the first to fourth channel layers 141, 142, 143, and 144. In an embodiment, the active structure may be formed to have a linear shape extending longitudinally in one direction, for example, the X direction, and may be formed to be spaced apart from an adjacent active structure in the Y direction. Side surfaces of the active structure in the Y direction may be coplanar with each other, and may be located on a straight line.

After filling a region from which a portion of the active region 105, portions of the sacrificial layers 120, and portions of the first to fourth channel layers 141, 142, 143, and 144 are removed with an insulating material, the device isolation layer 110 may be formed by partially removing the insulating material such that the active region 105 protrudes. In an embodiment, an upper surface of the device isolation layer 110 may be formed to be lower than an upper surface of the active region 105.

Referring to FIGS. 11A and 12C, sacrificial gate structures 200 and gate spacer layers 164 may be formed on the active structure in block S30.

The sacrificial gate structure 200 may be a sacrificial structure formed by a subsequent process in a region in which the gate dielectric layer 162 and the gate electrode 165 are disposed on the channel structures 140, as illustrated in FIG. 2. In an embodiment, the sacrificial gate structure 200 may have a linear shape intersecting the active structure to extend longitudinally in one direction. For example, in an embodiment the sacrificial gate structures 200 may extend in the Y direction, and may be arranged to be spaced apart from each other in the X direction.

In an embodiment, the sacrificial gate structure 200 may include first and second sacrificial gate layers 202 and 205 and a mask pattern layer 206, sequentially stacked (e.g., in the Z direction). The first and second sacrificial gate layers 202 and 205 may be patterned using the mask pattern layer 206. In an embodiment, the first and second sacrificial gate layers 202 and 205 may be an insulating layer and a conductive layer, respectively. However, embodiments of the present disclosure are not necessarily limited thereto, and the first and second sacrificial gate layers 202 and 205 may be formed as a single layer. For example, the first sacrificial gate layer 202 may include silicon oxide, and the second sacrificial gate layer 205 may include polysilicon. The mask pattern layer 206 may include silicon oxide and/or silicon nitride.

Gate spacer layers 164 may be formed on both sidewalls of the sacrificial gate structures 200. The gate spacer layers 164 may be formed of a low-K material, and may include, for example, at least one of SiO, SiN, SiCN, SiOC, SiON, or SiOCN.

Referring to FIGS. 11A and 12D, an etching process may be performed using the sacrificial gate structures 200 as an etch mask to form a recess region passing through the active structure and exposing the active region 105 in block S40.

The sacrificial layers 120 and the first to fourth channel layers 141, 142, 143, and 144, exposed from the sacrificial gate structures 200, may be partially removed to form recess regions RC, and the sacrificial layers 120 may be partially removed. As a result, the first to fourth channel layers 141, 142, 143, and 144 may form channel structures 140 having a limited length in the X direction.

Referring to FIGS. 11A and 12E, a liner may be formed on side surfaces of the sacrificial gate structures 200, side surfaces of the exposed plurality of sacrificial layers 120, and side surfaces of the exposed plurality of channel layers 140, and a molded layer 151 may be formed on the exposed active region 105 in block S50.

In an embodiment, the molded layer 151 may be formed by growing from the active region 105 exposed through a bottom surface of the recess region RC by, for example, a selective epitaxial process. Due to the liner L, the selective epitaxial process may not proceed on the side surfaces of the sacrificial gate structures 200, the side surfaces of the plurality of sacrificial layers 120, and the side surfaces of the plurality of channel layers 140. The molded layer 151 may have a different composition from a peripheral source/drain region 152 to be formed subsequently. For example, the molded layer 151 may include a relatively higher concentration of germanium (Ge) than the peripheral source/drain region 152 formed subsequently. The molded layer 151 may be spaced apart from the sacrificial layers 120 and the first to fourth channel layers 141, 142, 143, and 144. In embodiments, a relative thickness of the molded layer 151 may be changed in various manners within a range in which the molded layer 151 is spaced from the sacrificial layers 120 and the first to fourth channel layers 141, 142, 143, and 144.

Referring to FIGS. 11A and 12F, the liner L may be removed, and a portion of each of the side surfaces of the exposed plurality of sacrificial layers 120 and a portion of an upper surface of the molded layer 151 may be etched in block S60.

In an embodiment, the sacrificial layers 120 may be selectively etched with respect to the channel structures 140 by, for example, a wet etching process, and may be removed to a predetermined depth from the side surface thereof in the X direction. The sacrificial layers 120 may have side surfaces that are concave in an inward direction by side etching as described above. However, embodiments of the present disclosure are not necessarily limited thereto and the specific shapes of the side surfaces of the sacrificial layers 120 may vary from that illustrated in FIG. 12F.

The molded layer 151 may be etched together with the sacrificial layers 120, and may be removed by a predetermined depth from an upper surface thereof. Depending on a difference in composition of materials included in the molded layer 151 and the sacrificial layers 120, etching selectivity may occur and a degree of etching may be changed. For example, when an etching material that reacts more strongly to a high concentration of germanium (Ge) is used, and a concentration of germanium (Ge) included in the molded layer 151 is higher than a concentration of germanium (Ge) included in the sacrificial layers 120, the upper surface of the molded layer 151 may be etched more deeply than the side surfaces of the sacrificial layers 120.

Referring to FIGS. 11A and 12G to 12H, a peripheral source/drain region 152 may be formed on each of the side surfaces of the plurality of sacrificial layers 120, each of the side surfaces of the plurality of channel layers 140, and the peripheral source/drain on the molded layer 151 in block S70, and first and second epitaxial layers 154 and 156 may be sequentially formed on the peripheral source/drain region 152 (e.g., in the Z direction) to form a central source/drain region (154 and 156) filling the recess region RC in block S80.

In an embodiment, the peripheral source/drain region 152 and the central source/drain region (154 and 156) may be grown on and formed from, for example, an upper surface of the active region 105, an upper surface of the molded layer 151, and side surfaces of the channel structure 140, by a selective epitaxial process. The peripheral source/drain region 152, the first epitaxial layer 154, and the second epitaxial layer 156 may be formed sequentially. The peripheral source/drain region 152, the first epitaxial layer 154, and the second epitaxial layer 156 may contain impurities by in-situ doping, and may have different compositions and/or a doping concentration from each other.

Referring to FIGS. 11B and 12I, in an embodiment a first interlayer insulating layer 192 may be partially formed, and the sacrificial gate structures and the sacrificial layers may be removed in block S90.

In an embodiment, the first interlayer insulating layer 192 may be formed by forming an insulating film covering the sacrificial gate structures 200 and the central source/drain region (154 and 156), and performing a planarization process.

The sacrificial gate structures 200 and the sacrificial layers 120 may be removed selectively with respect to the gate spacer layers 164, the first interlayer insulating layer 192, and the channel structures 140. In an embodiment, the sacrificial gate structures 200 may be first removed to form upper gap regions UR, and then the sacrificial layers 120 exposed through the upper gap regions UR may be removed to form lower gap regions LR.

For example, in an embodiment in which the sacrificial layers 120 include silicon germanium (SiGe) and the channel structures 140 include silicon (Si), the sacrificial layers 120 may be selectively removed with respect to the channel structures 140 by performing a wet etching process. For example, in an embodiment in which the sacrificial layers 120 include a relatively high concentration of germanium (Ge) and the peripheral source/drain regions 152 include a relatively low concentration of germanium (Ge), the sacrificial layers 120 may be selectively removed with respect to the peripheral source/drain region 152.

Referring to FIGS. 11B and 12J, gate dielectric layers 162 and a gate electrode 165 may be formed to prepare gate structures 160 in block S100.

The gate dielectric layers 162 and the gate electrode 165 may be formed to fill the upper gap regions UR and the lower gap regions LR. The gate dielectric layers 162 may be formed to conformally cover inner surfaces of the upper gap regions UR and the lower gap regions LR. The gate electrode 165 may be formed to completely fill the upper gap regions UR and the lower gap regions LR, and may be then removed in the upper gap regions UR from the top by a predetermined depth, together with the gate dielectric layers 162 and the gate electrode 165.

Afterwards, a first interlayer insulating layer 192 may be further formed on the gate structures 160.

Referring to FIGS. 11B and 12K, the entire structure formed with reference to FIGS. 12A to 12J may be attached to a carrier substrate, the substrate 101 may be removed, and a substrate insulating layer 194 may be formed in block S110.

In an embodiment contact plugs and interconnection lines, connected to the gate structures 160, may be further formed on the gate structures 160. The carrier substrate SUB may be attached to the first interlayer insulating layer 192 to perform a process on a lower surface of the substrate 101 in FIG. 12J. In the following drawings, to facilitate understanding, the entire structure is illustrated rotated or inverted in a mirror image of the structure illustrated in FIG. 12J.

The substrate 101 may be removed from an upper surface of the substrate 101. In an embodiment, the substrate 101 may be removed and thinned by, for example, a lapping process, a grinding process, or a polishing process, and a remaining region may also be removed by an etching process and/or an oxidation process. However, a thickness from which the substrate 101 is removed may be changed in various embodiments. In some embodiments, the substrate 101 may not be completely removed, and a portion of the substrate 101 may remain. In this embodiment, the active region 105 may remain on an uppermost surface of the gate structures 160.

The substrate insulating layer 194 may be formed in a region from which the substrate 101 is removed. When a portion of the device isolation layer 110 remains without being removed along with the substrate 101, the substrate insulating layer 194 may include the remaining device isolation layer 110.

Referring to FIGS. 11B and 12L, a contact hole CTH passing through the substrate insulating layer 194 (e.g., in the Z direction) may be formed to expose the molded layer 151 in block S120.

In an embodiment, the contact hole CTH may be formed along a side surface of a lower portion of the kink portion k of the backside contact plug 180 of FIG. 2 to pass through the substrate insulating layer 194 (e.g., in the Z direction). The molded layer 151 may be exposed through the contact hole CTH. In an embodiment, the contact hole CTH may have a width (e.g., length in the X direction) that increases as a distance away from the molded layer 151 increases.

Referring to FIGS. 11B and 12M, the molded layer 151 may be removed to expose the peripheral source/drain region 152 in block S130.

In an embodiment, the molded layer 151 exposed through the contact hole CTH may be selectively removed by an etching process. In this operation, the peripheral source/drain region 152 may be exposed, and may serve as an etch stop. Therefore, the peripheral source/drain regions 152 may be used without forming a separate etch stop layer, the process may be simplified, costs for the process may be reduced, and reliability of the semiconductor device may be increased.

Referring to FIGS. 11B and 12N, a portion of the peripheral source/drain region 152 and a portion of the first epitaxial layer 154 may be etched in block S140.

In an embodiment, the first epitaxial layer 154 may be exposed by removing the portion of the source/drain region 152 and the portion of the first epitaxial layer 154 surrounding the contact hole CTH. As a result, a shape of a lower surface of the source/drain structure 150, in a similar manner to the semiconductor device 100 of FIG. 2, may be formed. In an embodiment in which a process of etching the portion of the peripheral source/drain region 152 and the portion of the first epitaxial layer 154 is not performed in the current process, a shape of a lower surface of the source/drain structure 150 of the semiconductor device 100A, as illustrated in FIG. 3, may be formed.

Referring to FIGS. 11B and 12O, a backside contact plug filling the contact hole CTH may be formed in block S150.

A metal-semiconductor compound layer 184 may be formed on the exposed peripheral source/drain region 152 and the first epitaxial layer 154. In an embodiment, the metal-semiconductor compound layer 184 may be formed by performing a metal-semiconductorization process, such as a silicidation process or the like, using the exposed source/drain structure 150.

In an embodiment, referring to FIGS. 11B and 12O together with FIG. 2, a lower interconnection 195 may be formed in block S160. The lower interconnection 195 may be prepared by forming a second interlayer insulating layer 196 covering the substrate insulating layer 194 and the backside contact plug 180, and then removing a portion of the second interlayer insulating layer 196 to expose the backside contact plug 180.

As a result, the semiconductor device 100 of FIGS. 1 and 2 may be manufactured. The semiconductor device 100 may be packaged in a state in which the lower interconnection 195 is located in an upper portion. However, embodiments of the present disclosure are not necessarily limited thereto.

A source/drain region may be reused as an etch stop layer in a backside process to provide a semiconductor device in which a process is simplified and reliability is increased.

Various advantages and effects of embodiments of the present disclosure are not limited to the above-described contents.

While non-limiting, example embodiments have been illustrated and described above, it will be apparent to those skilled in the art that modifications and variations could be made without departing from the scope of the present disclosure.

What is claimed is:

1. A semiconductor device comprising:
a substrate insulating layer;
a gate structure extending in a first direction on the substrate insulating layer; and
a first source/drain structure and a second source/drain structure are arranged on one side of the gate structure, the first source/drain structure and the second source/drain structure are spaced apart from each other in the first direction,
wherein the first source/drain structure includes a first central source/drain region, a first peripheral source/drain region surrounding side and lower surfaces of the first central source/drain region, and a first molded layer directly contacting a lower surface of the first peripheral source/drain region,
the second source/drain structure includes a second central source/drain region, a second peripheral source/drain region surrounding side and lower surfaces of the second central source/drain region, a second molded layer disposed below the second peripheral source/drain region, and an etch stop layer disposed between the second peripheral source/drain region and the second molded layer,
the etch stop layer includes a material that is different from a material of the second peripheral source/drain region and a material of the second molded layer,
the first central source/drain region has a first conductivity-type, and
the second central source/drain region has a second conductivity-type that is different from the first conductivity-type.

2. The semiconductor device of claim 1, wherein the first peripheral source/drain region comprises a plurality of protrusions extending from a side surface of the first peripheral source/drain region facing the gate structure and protruding towards the gate structure.

3. The semiconductor device of claim 2, wherein a protrusion length of each of the plurality of protrusions is greater than a distance between a lower end of the first central source/drain region and a lower end of the first peripheral source/drain region.

4. The semiconductor device of claim 2, further comprising:
a plurality of inner spacers extending from a side surface of the second peripheral source/drain region facing the gate structure and protruding towards the gate structure,
wherein the plurality of inner spacers include a material that is different from the material of the second peripheral source/drain region.

5. The semiconductor device of claim 4, wherein:
the plurality of inner spacers comprises silicon nitride; and
the second peripheral source/drain region comprises silicon germanium.

6. The semiconductor device of claim 1, wherein a distance between a lower end of the first central source/drain region and a lower end of the first peripheral source/drain region is less than a distance between the lower end of the first peripheral source/drain region and a lower end of the first molded layer.

7. The semiconductor device of claim 1, wherein:
the first conductivity-type is a P-type; and
the second conductivity-type is an N-type.

8. The semiconductor device of claim 7, wherein:
the second central source/drain region comprises at least one of phosphorus, arsenic, or antimony; and
the second peripheral source/drain region comprises silicon germanium.

9. The semiconductor device of claim 7, wherein the first central source/drain region and the first peripheral source/drain region comprise silicon germanium,
wherein a germanium concentration of the first central source/drain region is greater than a germanium concentration of the first peripheral source/drain region.

10. The semiconductor device of claim 9, wherein the first molded layer comprises silicon germanium,
wherein a germanium concentration of the first molded layer is greater than the germanium concentration of the first peripheral source/drain region.

11. The semiconductor device of claim 9, wherein the second peripheral source/drain region and the second molded layer comprise silicon germanium,
wherein a germanium concentration of the second molded layer is greater than a germanium concentration of the second peripheral source/drain region.

12. A semiconductor device comprising:
a substrate insulating layer;
a gate structure extending in a first direction on the substrate insulating layer;
a plurality of source/drain structures spaced apart from each other in the first direction on one side of the gate structure, the plurality of source/drain structures including a first group of source/drain structures and a second group of source/drain structures; and
a backside contact plug passing through the substrate insulating layer and connected to the first group of source/drain structures,
wherein each of the plurality of source/drain structures includes a central source/drain region and a peripheral source/drain region surrounding the central source/drain region,
the second group of source/drain structures further include a molded layer directly contacting a lower surface of the peripheral source/drain regions.

13. The semiconductor device of claim 12, wherein:
a lower surface of the backside contact plug is coplanar with a lower surface of the substrate insulating layer,
wherein a lower interconnection is electrically connected to the backside contact plug and is disposed on the lower surface of the backside contact plug.

14. The semiconductor device of claim 12, further comprising a frontside contact plug connected to the second group of source/drain structures and disposed above the second group of source/drain structures.

15. A semiconductor device comprising:
a gate structure extending in one direction;
a source/drain structure disposed outside the gate structure; and
a backside contact plug electrically connected to the source/drain structure and disposed below the source/drain structure,
wherein the source/drain structure includes a central source/drain region and a peripheral source/drain region surrounding the central source/drain region,
the peripheral source/drain region includes a plurality of protrusions protruding towards the gate structure,
the peripheral source/drain region includes a non-silicon element in a first concentration,
the central source/drain region includes a first epitaxial layer including a non-silicon element in a second concentration that is higher than the first concentration, the first epitaxial layer covering an inner side surface of the peripheral source/drain region, and a second epitaxial layer including a non-silicon element in a third concentration that is higher than the second concentration, the second epitaxial layer is disposed on the first epitaxial layer, and
the backside contact plug is in direct contact with the peripheral source/drain region.

16. The semiconductor device of claim 15, wherein the non-silicon element is germanium.

17. The semiconductor device of claim 15, wherein:
the backside contact plug has an upper surface that is convex in an upward direction, the upper surface of the backside contact plug is in direct contact with the central source/drain region; and
wherein an upper end of the backside contact plug is positioned at a higher level than a lower end of the gate structure.

18. The semiconductor device of claim 15, wherein:
the peripheral source/drain region covers at least a portion of a side surface, and a lower surface of the central source/drain region;
the backside contact plug has an upper surface that is convex in a downward direction; and
the central source/drain region and the backside contact plug are spaced apart from each other.

19. The semiconductor device of claim 15, wherein the backside contact plug comprises a metal-semiconductor compound layer defining an upper surface of the backside contact plug.

20. The semiconductor device of claim 15, wherein:
the backside contact plug comprises a kink portion having a minimum width; and
the kink portion is located closer to an upper end of the backside contact plug than to a lower end of the backside contact plug.
